(19) United States
(12) Patent Application Publication
(10) Pub. No.: US 2013/0069500 A1
(43) Pub. Date: Mar. 21, 2013

(54) ASSEMBLY STRUCTURE AND DISPLAY DEVICE THEREWITH

(71) Applicants: Hung-Te Chan, New Taipei City (TW); Sheng-Chieh Yang, New Taipei City (TW); Chi-Wei Kuo, New Taipei City (TW)

(72) Inventors: Hung-Te Chan, New Taipei City (TW); Sheng-Chieh Yang, New Taipei City (TW); Chi-Wei Kuo, New Taipei City (TW)

(21) Appl. No.: 13/448,406

(22) Filed: Apr. 17, 2012

(30) Foreign Application Priority Data
Sep. 21, 2011 (TW) 100133915

(51) Int. Cl. B23P 19/00; H05K 5/02

(52) U.S. Cl. 312/223.1; 29/700

(57) ABSTRACT

An assembly structure for assembling a first casing and a second casing is disclosed. The first casing covers a panel module cooperatively with the second casing. The assembly structure includes a wedging portion, a fixing structure and an engaging structure. The wedging portion has a first plate and a second plate. The fixing structure is disposed on the first plate for fixing the second casing in a position corresponding to an edge of a bottom surface of the panel module. The engaging structure protrudes from the second plate for engaging with an engaging portion of the first casing, so as to fix the first casing in a position corresponding to a side of the panel module.

### BACKGROUND OF THE INVENTION

1. Field of the Invention

The disclosure relates to an assembly structure and a display device therewith, and more particularly, to an assembly structure adapted to different casings as well as adapted to a narrow bezel and a display device therewith.

2. Description of the Prior Art

Generally speaking, an upper casing and a lower casing of a conventional liquid crystal display device are usually fastened by screws. The screws are disposed through holes on the lower casing and then screwed onto screw bosses on an edge of the upper casing. Accordingly, screw heads of the screws can press the lower casing onto top surfaces of the screw bosses, so as to fix the upper casing and the lower casing of the conventional liquid crystal display device.

However, since the screw bosses for fixing the upper casing and the lower casing occupy specific volume, it requires a specific width of the bezel of the upper casing of the conventional liquid crystal display device. Accordingly, a width of the bezel of the upper casing of the conventional liquid crystal display device is hard to be shortened. As a result, the conventional liquid crystal display device with the screw bosses can not meet the tide of a narrow bezel in the market.

### SUMMARY OF THE INVENTION

Therefore, according to the disclosure, an assembly structure for assembling a first casing and a second casing is disclosed. The first casing and the second casing cover a panel module cooperatively. The assembly structure includes a wedging portion, a fixing structure and an engaging structure. The wedging portion has a first plate and a second plate. The fixing structure is disposed on the first plate for fixing the second casing in a position corresponding to an edge of a bottom surface of the panel module. The engaging structure protrudes from the second plate for engaging with an engaging portion of the first casing, so as to fix the first casing in a position corresponding to a lateral side of the panel module.

Furthermore, according to the disclosure, a display device includes a panel module, a first casing, a second casing and an assembly structure. An engaging portion is formed in a position corresponding to a lateral side of the panel module. The first casing and the second casing cover the panel module cooperatively. The assembly structure is for assembling the first casing and the second casing. The assembly structure includes a wedging portion, a fixing structure and an engaging structure. The wedging portion includes a first plate and a second plate. The fixing structure is disposed on the first plate for fixing the second casing in a position corresponding to an edge of a bottom surface of the panel module. An engaging structure protrudes from the second plate for engaging with the engaging portion of the first casing, so as to fix the first casing in the position corresponding to the lateral side of the panel module.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 is a partly sectional diagram of a display device according to an embodiment of the disclosure.

FIG. 2 is a diagram of an assembly structure according to the embodiment of the disclosure.

FIG. 3 is a diagram of a wedging portion located in a first according to the embodiment of the disclosure.

FIG. 4 is the wedging portion located in a second position according to the embodiment of the disclosure.

FIG. 5 is a diagram of the assembly structure in another view according to the embodiment of the disclosure.

FIG. 6 is a diagram of an assembly structure according to another embodiment of the disclosure.

FIG. 7 is a partly enlarged diagram of a first casing according to another embodiment of the disclosure.

FIG. 8 is an assembly diagram of the assembly structure and the first casing according to another embodiment of the disclosure.

### DETAILED DESCRIPTION

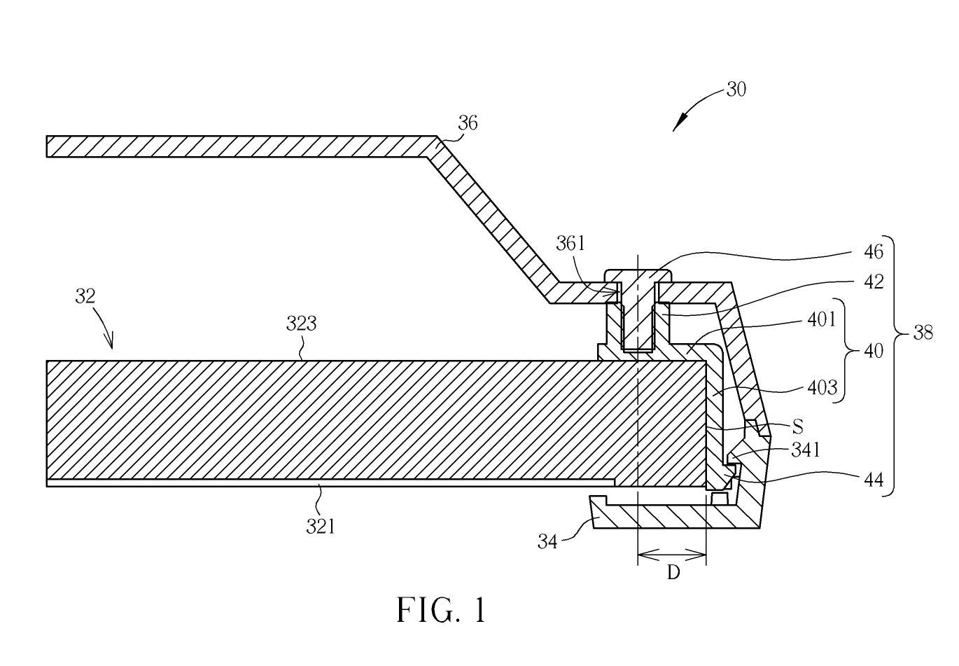

Please refer to FIG. 1, FIG. 1 is a partly sectional diagram of a display device 30 according to an embodiment of the disclosure. As shown in FIG. 1, the display device 30 includes a panel module 32, a first casing 34, a second casing 36 and an assembly structure 38. The first casing 34 and the second casing 36 cover the panel module 32 cooperatively. The assembly structure 38 is for assembling the first casing 34 and the second casing 36, so as to fix the first casing 34 and the second casing 36. In this embodiment, the display device 30 can be, but not limited to, a liquid crystal display device. In practical application, the first casing 34 can be an upper casing of the display device 30, such as a bezel, and the second casing 36 can be a lower casing of the display device 30.

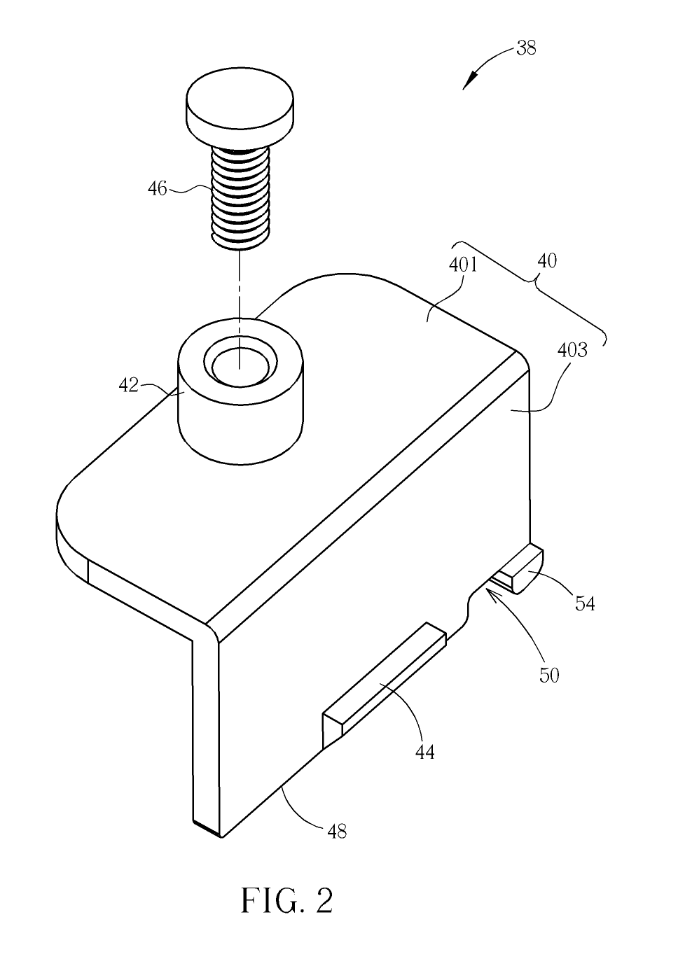

The panel module 32 has a top surface 321 and a bottom surface 323. The panel module 32 is for displaying frames, such that a user is capable of inputting an instruction by the frames. An engaging portion 341 is formed in a position corresponding to a lateral side S on the first casing 34 of the panel module 32. Please refer to FIG. 1 and FIG. 2. FIG. 2 is a diagram of the assembly structure 38 according to the embodiment of the disclosure. As shown in FIG. 1 and FIG. 2, the assembly structure 38 includes a wedging portion 40, a fixing structure 42 and an engaging structure 44. The wedging portion 40 can be an L-shaped structure and includes a first plate 401 and a second plate 403. The first plate 401 and the second plate 403 are respectively two sides of the L-shaped structure substantially perpendicular to each other. The fixing structure 42 is disposed on the first plate 401, and the engaging structure 44 protrudes from the second plate 403. The fixing structure 42 is apart from the second plate 403 by a distance D along a planar direction of the first plate 401.

A shape of the aforesaid L-shaped structure of the wedging portion 40 can be substantially identical to a shape of the bottom surface 323 on the lateral side S of the panel module 32. Accordingly, when the wedging portion 40 is disposed on the panel module 32, the first plate 401 and the second plate 403 of the wedging portion 40 can respectively attach to the bottom surface 323 and the lateral side S of the panel module 32. Since the fixing structure 42 is apart from the second plate 403 by the distance D along the planar direction of the first plate 401, the fixing structure 42 is apart from the lateral side S of the panel module 32 by the distance D, that is, the fixing structure 42 of the assembly structure 38 can fix the second casing 36 in a position apart from the lateral side S by the distance D. In other words, the fixing structure 42 can be used for fixing the second casing 36 in a position corresponding to an edge of the bottom surface 323 of the panel module 32. On the other hand, since the engaging portion 341 is formed on the first casing 34 in the position corresponding to the lateral side S of the panel module 32, the assembly structure 38 can fix the first casing 34 in the position corresponding to the lateral side S of the panel module 32 when the engaging structure 44 of the assembly structure 38 engages with the engaging portion 341 of the first casing 34.

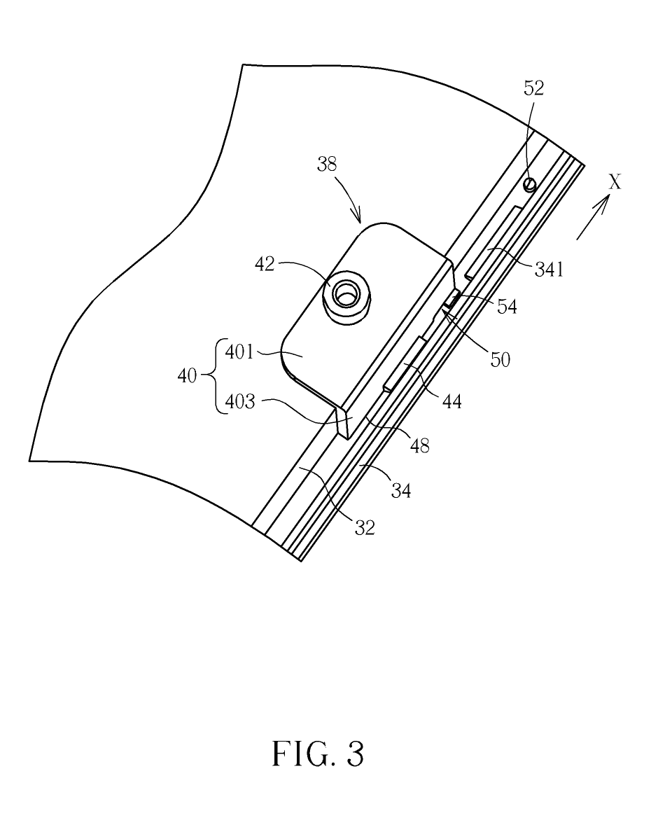

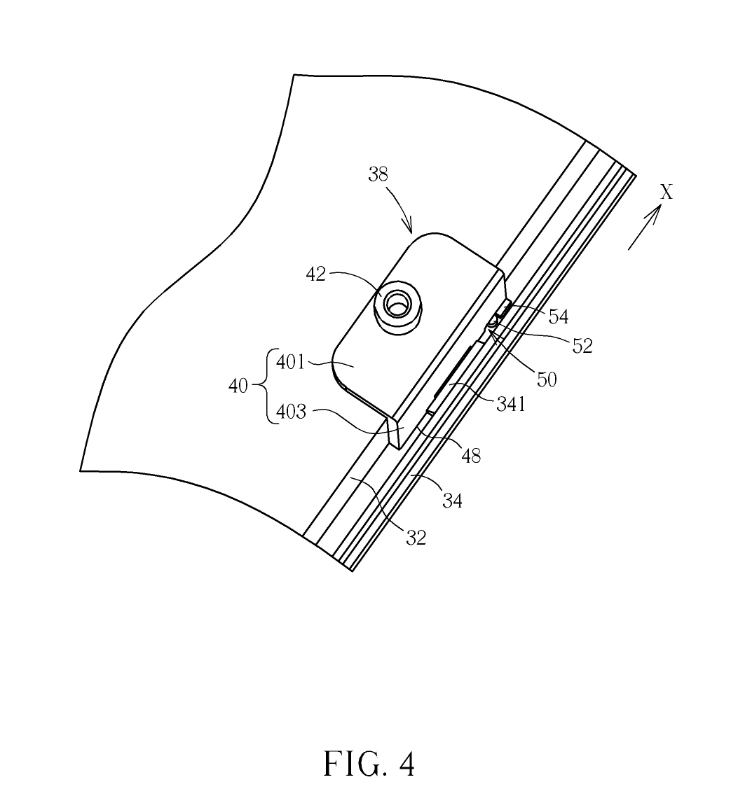

As shown in FIG. 1 and FIG. 2, the assembly structure 38 further includes a screw component 46 and a sliding structure 48, and the second casing 36 includes a through hole 361. The screw component 46 can pass through the through hole 361, such that the screw component 46 screws onto the fixing structure 42. The sliding structure 48 is connected to the second plate 403 and disposed on a bottom side of the second plate 403 for guiding the wedging portion 40 of the assembly structure 38 to slide relative to the first casing 34. In this embodiment, the sliding structure 48 and the second plate 403 can be integrally formed. In addition, the assembly structure 38 further includes a first positioning portion 50 disposed on a side of the sliding structure 48. Please refer to FIG. 3 and FIG. 4. FIG. 3 is a diagram of the wedging portion 40 located in a first position according to the embodiment of the disclosure. FIG. 4 is the wedging portion 40 located in a second position according to the embodiment of the disclosure. As shown in FIG. 3 and FIG. 4, the first casing includes a second positioning portion 52. Since the sliding structure 48 can guide the wedging portion 40 to slide relative to the first casing 34, the wedging portion 40 of the assembly structure 38 can be disposed in the first position on the panel module 32 during assembly process, as shown in FIG. 3. Then, the wedging portion 40 is pushed along an assembly direction X, as shown in FIG. 3. In the meanwhile, the engaging structure 44 of the assembly structure 38 can slide underneath the engaging portion 341 of the first casing 34 along the assembly direction X relative to the first casing 34, until the wedging portion 40 of the assembly structure 38 slides to the second position, i.e. an engaging position, as shown in FIG. 4. In the meanwhile, the engaging structure 44 of the assembly structure 38 can engage with the engaging portion 341 of the first casing 34, and the first positioning portion 50 of the assembly structure 38 engages with the second positioning portion 52 of the first casing 34, so as to fix the assembly structure 38 on the first casing 34.

Furthermore, when the first positioning portion 50 of the assembly structure 38 engages with the second positioning portion 52 of the first casing 34, the fixing structure 42 of the assembly structure 38 can align with the through hole 361 of the second casing 36, as shown in FIG. 1. In the meanwhile, the screw component 46 of the assembly structure 38 can pass through the through hole 361 of the second casing 36 more precisely, so as to be screwed on the fixing structure 42 of the assembly structure 38. In this embodiment, the screw component 46 can be preferably a M4 screw, and the fixing structure 42 of the assembly structure 38 can be preferably a screw boss adapted to the aforesaid M4 screw. As known above, the screw component 46 can screw the screw boss and press the second casing 36 on a top surface of the screw boss.

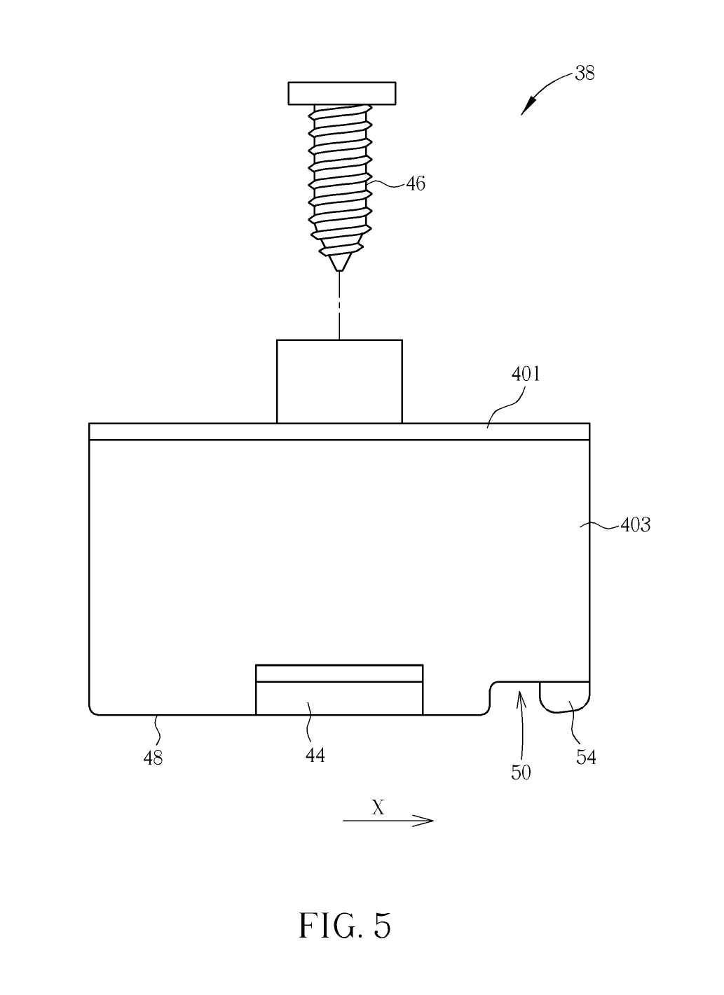

Please refer to FIG. 5. FIG. 5 is a diagram of the assembly structure 38 in another view according to the embodiment of the disclosure. As shown in FIG. 5, the assembly structure 38 further includes a guiding structure 54 disposed on a side of the first positioning portion 50. In structural design, a distance between the guiding structure 54 and the first plate 401 along the assembly direction X is decreasing. When the wedging portion 40 slides relative to the first casing 34 from the first position shown in FIG. 3 to the second position shown in FIG. 4, the guiding structure 54 guides the first positioning portion 50 of the assembly structure 38 to engage with the second positioning portion 52 of the first casing 34.

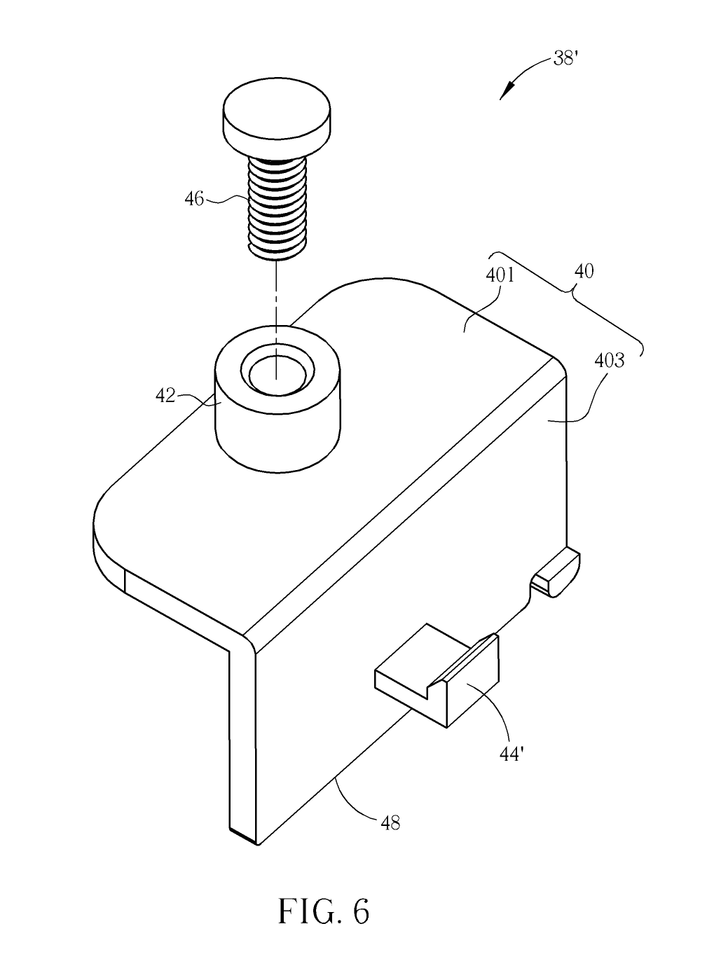

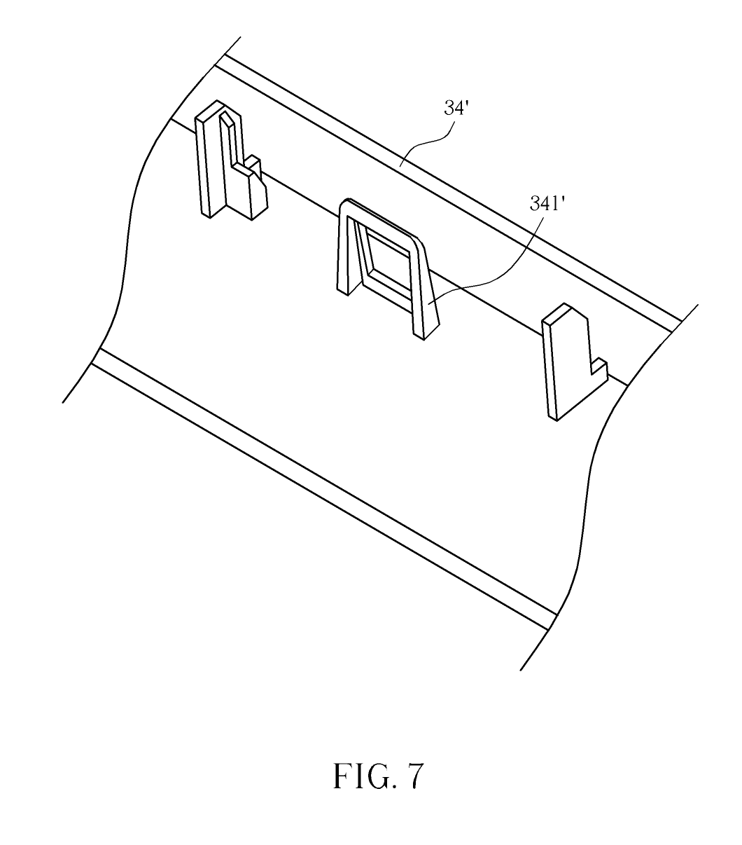

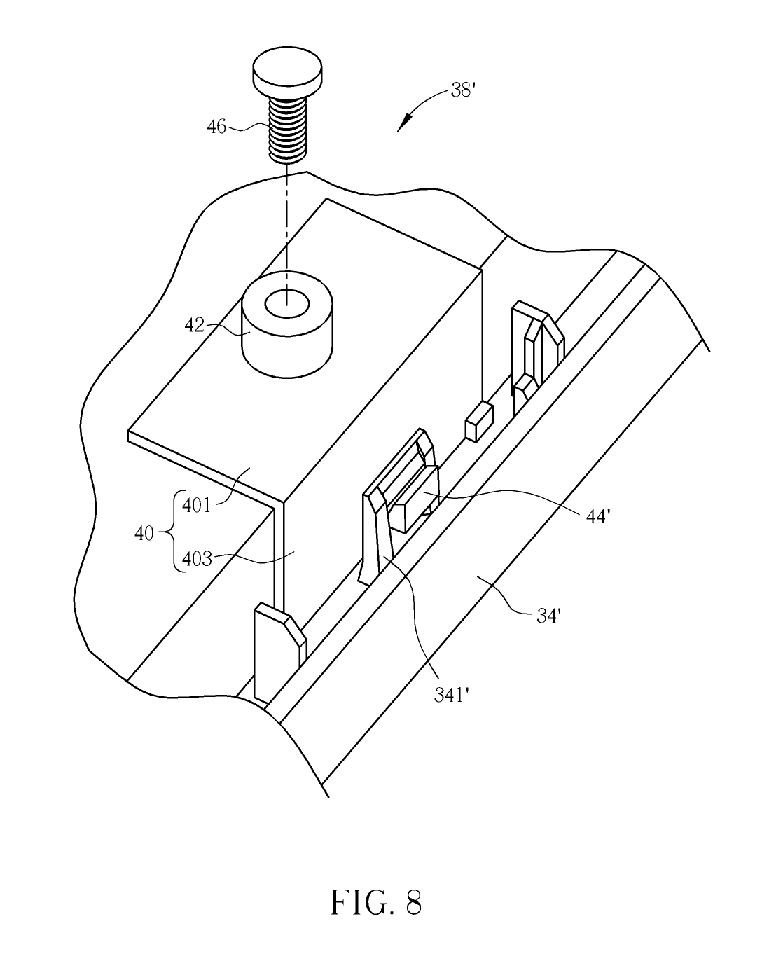

Please refer to FIG. 6 to FIG. 8. FIG. 6 is a diagram of an assembly structure 38′ according to another embodiment of the disclosure. FIG. 7 is a partly enlarged diagram of a first casing 34′ according to another embodiment of the disclosure. FIG. 8 is an assembly diagram of the assembly structure 38′ and the first casing 34′ according to another embodiment of the disclosure. As shown in FIG. 6 to FIG. 8, an engaging structure 44′ of the assembly structure 38′ is a hook, and an engaging portion 341′ of the first casing 34′ is a slot. In addition, the first positioning portion 50 is omitted for the assembly structure 38′, and the second positioning portion 52 is omitted for the first casing 34′. It should be noticed that the assembly structure 38′ can also keep the first positioning portion 50 and the first casing 34′ can also keep the second positioning portion 52. In other words, it depends on practical demands to determine whether to keep the first positioning portion 50 and the second positioning portion 52 or not. During the assembly process, the engaging structure 44′ of the assembly structure 38′ can directly engage with the engaging portion 341′ of the first casing 34′. In the meanwhile, the hook engages with the slot, and an inner side of the slot constrains an outer side of the hook. In such a manner, the wedging portion 40 of the assembly structure 38′ can be fixed in an engaging position, as shown in FIG. 8. It should be noticed that components with the same denotes in FIG. 6 and in FIG. 2 as well as in FIG. 8 and in FIG. 4 represent same structures and functions, and it is omitted herein for simplicity.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An assembly structure for assembling a first casing and a second casing, the first casing and the second casing covering a panel module cooperatively, the assembly structure comprising:
a wedging portion comprising a first plate and a second plate;
a fixing structure disposed on the first plate for fixing the second casing in a position corresponding to an edge of a bottom surface of the panel module; and
an engaging structure protruding from the second plate for engaging with an engaging portion of the first casing, so as to fix the first casing in a position corresponding to a lateral side of the panel module.

2. The assembly structure of claim 1, wherein the wedging portion is an L-shaped structure, and the first plate and the second plate are respectively two sides of the L-shaped structure perpendicular to each other.

3. The assembly structure of claim 1, further comprising a sliding structure connected to the second plate for guiding the wedging portion to slide relative to the first casing, such that the engaging structure slides underneath the engaging portion along an assembly direction.

4. The assembly structure of claim 3, further comprising a first positioning portion disposed on a side of the sliding structure for engaging a second positioning portion of the first casing when the wedging portion slides to an engaging position relative to the first casing.

5. The assembly structure of claim 4, further comprising a guiding structure disposed on a side of the first positioning portion, a distance between the guiding structure and the first plate along the assembly direction being decreasing, and the guiding structure guiding the first positioning portion to engage with the second positioning portion of the first casing when the wedging portion slides relative to the first casing along the assembly direction.

6. The assembly structure of claim 1, further comprising a screw component, wherein the fixing structure is a screw boss, and the screw component screws the screw boss and presses the second casing onto a top surface of the screw boss.

7. The assembly structure of claim 1, wherein the engaging structure is a hook, and the engaging portion is a slot.

8. The assembly structure of claim 7, wherein an inner side of the slot constrains an outer side of the hook when the hook engages with the slot, so as to fix the wedging portion in an engaging position.

9. A display device, comprising:
a panel module;
a first casing whereon an engaging portion is formed in a position corresponding to a lateral side of the panel module;
a second casing, the first casing and the second casing covering the panel module cooperatively; and
an assembly structure for assembling the first casing and the second casing, the assembly structure comprising:
a wedging portion comprising a first plate and a second plate;
a fixing structure disposed on the first plate for fixing the second casing in a position corresponding to an edge of a bottom surface of the panel module; and
an engaging structure protruding from the second plate for engaging with the engaging portion of the first casing, so as to fix the first casing in the position corresponding to the lateral side of the panel module.

10. The display device of claim 9, wherein the wedging portion is an L-shaped structure, and the first plate and the second plate are respectively two sides of the L-shaped structure perpendicular to each other.

11. The display device of claim 9, wherein the assembly structure further comprises a sliding structure connected to the second plate for guiding the wedging portion to slide relative to the first casing, such that the engaging structure slides underneath the engaging portion along an assembly direction.

12. The display device of claim 11, wherein the assembly structure further comprises a first positioning portion disposed on a side of the sliding structure, the first casing comprises a second positioning portion, and the first positioning portion is used for engaging the second positioning portion of the first casing when the wedging portion slides to an engaging position relative to the first casing.

13. The display device of claim 12, wherein the assembly structure further comprises a guiding structure disposed on a side of the first positioning portion, a distance between the guiding structure and the first plate along the assembly direction is decreasing, and the guiding structure guides the first positioning portion to engage with the second positioning portion of the first casing when the wedging portion slides relative to the first casing along the assembly direction.

14. The display device of claim 9, wherein the assembly structure further comprises a screw component, the fixing structure is a screw boss, and the screw component screws the screw boss and presses the second casing onto a top surface of the screw boss.

15. The display device of claim of claim 9, wherein the engaging structure is a hook, and the engaging portion is a slot.

16. The display device of claim of claim 9, wherein an inner side of the slot constrains an outer side of the hook when the hook engages with the slot, so as to fix the wedging portion in an engaging position.
